(19) United States
(12) Patent Application Publication
(10) Pub. No.: US 2015/0294950 A1
(43) Pub. Date: Oct. 15, 2015

(54) METHOD FOR TERNARY WAFER BONDING AND STRUCTURE THEREOF

(71) Applicant: NATIONAL CENTRAL UNIVERSITY, TAOYUAN COUNTY (TW)

(72) Inventors: CHENG-YI LIU, TAOYUAN (TW); YI-CHIN LIN, TAOYUAN COUNTY (TW)

(21) Appl. No.: 14/487,330

(22) Filed: Sep. 16, 2014

(30) Foreign Application Priority Data
Apr. 11, 2014 (TW) 103113357

(51) Int. Cl. H01L 23/00

(52) U.S. Cl. CPC H01L 24/33; H01L 24/83; H01L 24/27; H01L 2924/10253; H01L 2224/2745; H01L 2224/27452; H01L 2224/29082; H01L 2224/29139; H01L 2224/29144; H01L 2224/83095; H01L 2224/83801; H01L 2924/01024; H01L 2924/01078; H01L 2924/20107; H01L 2224/83911; H01L 2224/32145

(57) ABSTRACT

The present invention relates to a method for ternary wafer bonding and the structure thereof. According to the present invention, silver island structures in the second bonding layer are distributed on the first bonding layer deposited on the surface of a single silicon wafer for forming a gold-silver combination structure, which is then bonded with another silicon wafer without any metal layers thereon at a low-temperature thermal process of 250° C. for completing gold-silver-silicon ternary wafer bonding. Thus, the temperature required for gold-silicon bonding is lowered and the process of wafer bonding is simplified as well. In addition, the quality of wafer bonding is also assured.

### FIELD OF THE INVENTION

The present invention relates generally to a method for wafer bonding and the structure thereof, and particularly to a method for ternary wafer bonding and the structure thereof by using an island bonding layer for forming the gold-silver-silicon bonding at a low temperature of 250° C. and thus forming the gold-silicon bonding.

### BACKGROUND OF THE INVENTION

In the fabrication of early electronic devices, integration of various materials can be done by the heterogeneous epitaxy or ion implantation technology in the fabrication processes of integrated circuits. The major problem of the heterogeneous epitaxy technology is the limitation imposed by lattice matching. High-quality epitaxial structures are often unattainable owing to lattice mismatch and thus affecting the functions of devices. IN addition, it is not feasible for growing an epitaxial structure with a thickness greater than 10 micrometers effectively and economically by using the heterogeneous epitaxy technology.

In recent years, a technique for integrating various material characteristics has been developed progressively. This technique, the wafer bonding technique, is done by wafer-bonding materials with mismatched lattices. The wafer bonding technique means that, after bonding two wafers, covalent bonds are formed for integrating the wafers and the bonding interface reaches a specific bonding strength by applying external energy and enabling reaction among the atoms at the bonding interface.

In the field of wafer bonding, the low-temperature bonding technique is a key item in research and application. The low-temperature bonding takes the difference between the thermal expansion coefficients of heterogeneous materials during bonding into account. In the heating and cooling processes, drastic thermal stress occurs and generates residual stress in the bonded devices, which result in the problems of fracture, bending, and yield. Moreover, there is a limitation in the bonding temperature of integrated circuits; high temperatures will damage the circuits as well as the crystalline structures. Consequently, the low-temperature bonding technique owns its advantage in industrial applications.

Currently, while operating the low-temperature bonding, there is a method of coating a layer of dielectric material with a low melting point on the surfaces of the two wafers and achieving the required bonding strength by a lower annealing temperature. For example, a layer of thin metal is vapor deposited on a silicon wafer. The eutectic temperature of gold and silicon is about 380° C. Thereby, when heated to this temperature, a silicon-gold alloy is produced, forming an integral contact interface, and thus achieving the purpose of bonding. Nonetheless, the temperature of heat treatment according to the method still needs to be lowered.

The Taiwan patent publication number TW 200839857 disclosed a method for low-temperature wafer bonding using gold/silver diffusion. First, a first wafer and a second wafer are selected. Then, gold and silver thin films are deposited on the first and second wafers by vapor deposition sequentially. Next, an ultrasonic vibrator is used for cleaning. Afterwards, the first and second wafers coated with metal thin films are placed in a furnace for performing a low-temperature bonding process at 100˜300° C. As a consequence, low-temperature wafer bonding can be attained by taking advantage of rapid diffusion at the gold/silver interface. Nonetheless, although this method can be performed at a low temperature between 100 and 300° C. and avoids the thermal stress problem due to difference in the thermal expansion coefficients between different materials, there is still room for improvement because surface coating is required for the two wafers to be bonded.

The US patent publication number US 20040262772 discloses methods for bonding wafers using a metal interlayer. According to the invention, after a dielectric layer is disposed between two silicon wafers, conductors such as aluminum, tungsten, gold, or silver coated with a gold or silver thin film are disposed on the dielectric layer. Then these conductors are used for bonding at a temperature below 300° C. Although this method can achieve low-temperature bonding below 300° C., the structure and method involved is extremely complicated. The relevant structures should be manufactured on the surface of two silicon wafers, respectively, and then aligned for bonding. It is disadvantageous to industrial applications.

Accordingly, the present invention discloses a method for ternary wafer bonding and the structure thereof, which satisfies the requirements of practicability, low cost, high product quality, and low-temperature bonding.

### SUMMARY

An objective of the present invention is to provide a method for ternary wafer bonding, which forms a gold-silver combination structure on the surface of a single silicon wafer for bonding with another silicon wafer without any metal layer on its surface. Thereby, the gold-silicon bonding can be lowered from 380° C. according to the prior art to 250° C.

Another objective of the present invention is to provide a method for ternary wafer bonding, in which the thermal process for wafer bonding is performed at a low temperature of only 250° C. Thereby, the influences of stress caused by high-temperature bonding can be avoided, and thus eliminating the possibility of fracture, bending, and lowered yield in silicon wafers.

Still another objective of the present invention is to provide a method for ternary wafer bonding. According to the present invention, after disposing a bonding layer of gold on the silicon wafer, another bonding layer of silver with island-patterned structures is disposed thereon for constructing a ternary bonding structure of gold, silver, and silver. In comparison with the method according to the prior art, the method according to the present invention is easier for process as well superior in the bonding quality.

A further objective of the present invention is to provide a method for ternary wafer bonding, which uses a special silver bonding layer for bonding excellently with a gold bonding layer. Thereby, after thermally processing silicon wafers at a temperature of 250° C., low-temperature gold-silicon bonding can be achieved.

In order to achieve the objectives described above, the present invention discloses a method for ternary wafer bonding and the structure thereof. The method comprises steps of vapor depositing a first bonding layer on a first silicon wafer; disposing a second bonding layer on the first bonding layer and the second bonding layer including a plurality of island structures distributed on the first bonding layer and exposing a portion of the first bonding layer; disposed a second silicon wafer on the second bonding layer; and performing thermal treatment for producing ternary bonding among the second silicon wafer, the first bonding layer, and the second bonding layer. According to the method, the temperature required for gold-silicon bonding can be lowered effectively.

### BRIEF DESCRIPTION OF THE DRAWINGS

FIG. 1 shows a flowchart according to the present invention;

FIG. 2 shows a structural schematic diagram during the operating process according to a preferred embodiment of the present invention;

FIG. 3 shows a side view of the structure according to a preferred embodiment of the present invention;

FIG. 4 shows a cross-sectional view of the structure after wafer bonding according to the present invention; and

FIG. 5 shows an electron microscope photo for experimental verification according to the present invention.

### DETAILED DESCRIPTION

In order to make the structure and characteristics as well as the effectiveness of the present invention to be further understood and recognized, the detailed description of the present invention is provided as follows along with embodiments and accompanying figures.

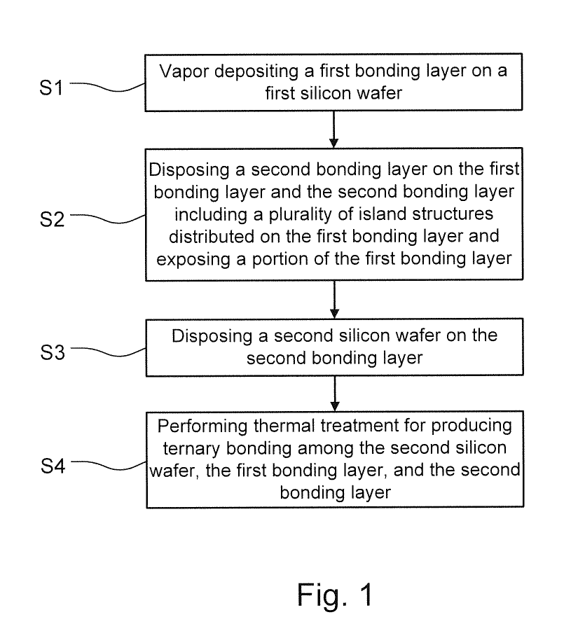

First, please refer to FIG. 1, which shows a flowchart according to the present invention. The method comprises:
Step S1: Vapor depositing a first bonding layer on a first silicon wafer;
Step S2: Disposing a second bonding layer on the first bonding layer and the second bonding layer including a plurality of island structures distributed on the first bonding layer and exposing a portion of the first bonding layer;
Step S3: Disposing a second silicon wafer on the second bonding layer; and
Step S4: Performing thermal treatment for producing ternary bonding among the second silicon wafer, the first bonding layer, and the second bonding layer.

According to the steps of the present invention described above, while bonding wafers, the bonding of the bonding layer and the silicon wafer can be done at an ambient temperature of 250° C., which is, in fact, a lower operating temperature in the technical field. Under a thermal process of 800˜1000° C., due to the inherent limitations in difference in thermal expansion coefficients for heterogeneous materials during bonding, significant thermal stress occurs during the heating and cooling processes, which will generate residual stress in the bonded devices and lead to the problems of fracture, bending, and reduced yield. The low temperature according to the present invention can avoid the problems. In addition, in the past, the temperature of thermal process has to be at least 380° C. for producing the gold-silicon bonding. By involving silver in the bonding according to the present invention, the temperature required for bonding gold and silicon can be lowered to 250° C. effectively.

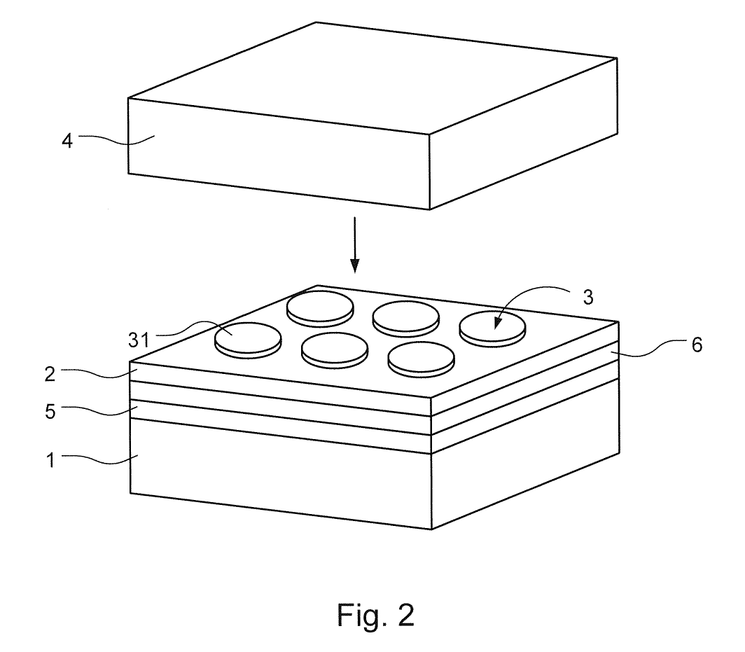

Please refer to FIG. 2, which shows a structural schematic diagram during the operating process according to a preferred embodiment of the present invention. According to the present invention, the first bonding layer 2 is first vapor deposited on the first silicon wafer 1. The material of the first bonding layer 2 is gold, which is one of the materials for forming bonding with the silicon wafer. In order to enhance the quality of wafer bonding, before depositing the first binding layer 2 on the first silicon wafer 1 by vapor deposition, an adhesion layer 5 and a barrier layer 6 will be deposited on the surface of the first silicon wafer 1 sequentially using vapor deposition. The material of the adhesion layer 5 is chrome; the material of the barrier layer 6 can be platinum. These are normal structures.

The critical technical feature of the present invention is disposing the second bonding layer 3 on the first bonding layer 2 as disclosed in the step S2. The material of the second bonding layer 3 is silver. Nonetheless, it is not a metal thin film, like the first bonding layer 2, the adhesion layer 5, or the barrier layer 6. Instead, it is patterned in island structures 31 and distributed on the first bonding layer 2. Beside, a portion of the first binding layer 2 is thereby exposed, instead of covering the first bonding layer 2 completely. Consequently, the basic conditions are all ready for ternary bonding.

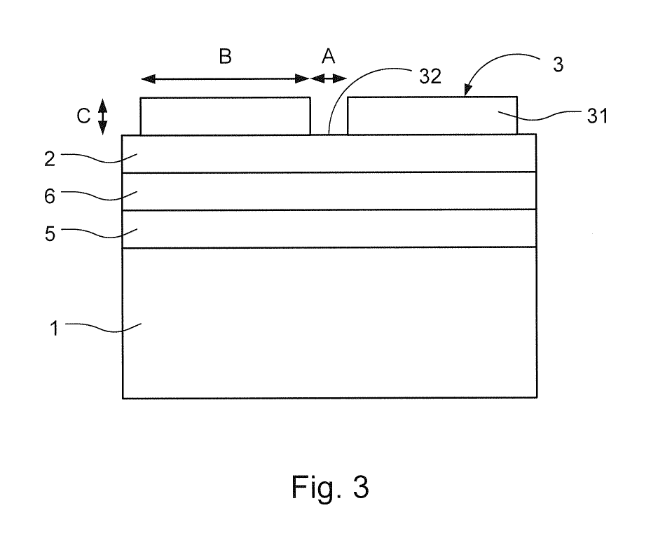

In addition to exposing a portion of the first bonding layer 2 from the patterned second bonding layer 3, the ratio of the pattern structures of the second bonding layer 3 according to the present invention is also controlled. Please refer to the side view shown in FIG. 3. The spacing 32 between the island structures 31 according to the present invention is spacing width A. Besides, the ratio of the diameter B to the height C of the island structures 31 is also well controlled. Thereby, the quality of wafer bonding can meet the requirements of industrial applications.

Concerning the ratio of the structures, the ratio of the diameter B to the height C of the island structures 31 according to the present invention is controlled between 900 and 1300; the ratio of the diameter B to the spacing width A of the spacing of the island structures 31 is between 4.75 and 4.50. Table 1 shows the practical data in operation:

TABLE 1

| | Spacing width | Diameter | Height |
|---|---|---|---|
| | (um) | (um) | (um) |
| Embodiment 1 | 200 | 950 | 1 |
| Embodiment 2 | 200 | 900 | 0.7 |

In addition to controlling the ratios of the structures, the thicknesses of the first bonding layer 2, the adhesion layer 5, and the barrier layer 6 are all 1 micrometer by vapor deposition; the thickness of the first silicon wafer 1 below these layers is approximately 380 micrometers.

After forming the second bonding layer 3 of silver island structure 31 on the first bonding layer 2, the next step is to place the second silicon wafer 4 to be bonded with the first silicon wafer 1 on the second bonding layer 3. The surface of the second silicon wafer 4 has been cleaned in advance by aqua regia for removing attached materials on the surface and thus assuring excellent bonding effect. According to the present invention, beside the surface cleaning for the second silicon wafer 4, no extra film coating is required. All layers are disposed on the surface of the first silicon wafer 1. This brings a prominent advantage in simplifying the process of wafer bonding.

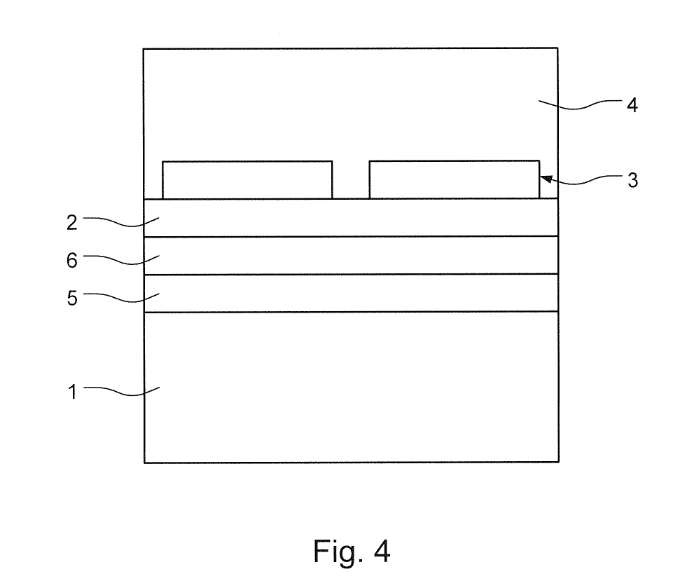

Finally, in the thermal treatment of the step S4, the second silicon wafer 4 will have ternary bonding with the first bonding layer 2 and the second bonding layer 3 concurrently, namely, forming a gold-silver-silicon ternary structure. This thermal process does not require an excessively high temperature. The bonding of the first and second silicon wafers 1, 4 can be achieved in a temperature of only 250° C., which is lower than the gold-silicon eutectic point, 380° C., for three hours in a vacuum furnace. Thanks to the adoption of silver as an element for ternary bonding, the gold-silicon eutectic point is lowered. Thereby, the temperature of thermal treatment can be reduced to 250° C. Please refer FIG. 4, which shows a structural schematic diagram of the first and second wafers 1, 4 after wafer bonding according to the present invention. At this moment, the first and second silicon wafers 1, 4 are bonded stably and tightly at the first and second bonding layers 2, 3 of the first silicon wafer 1 and the surface of the second silicon wafer 2.

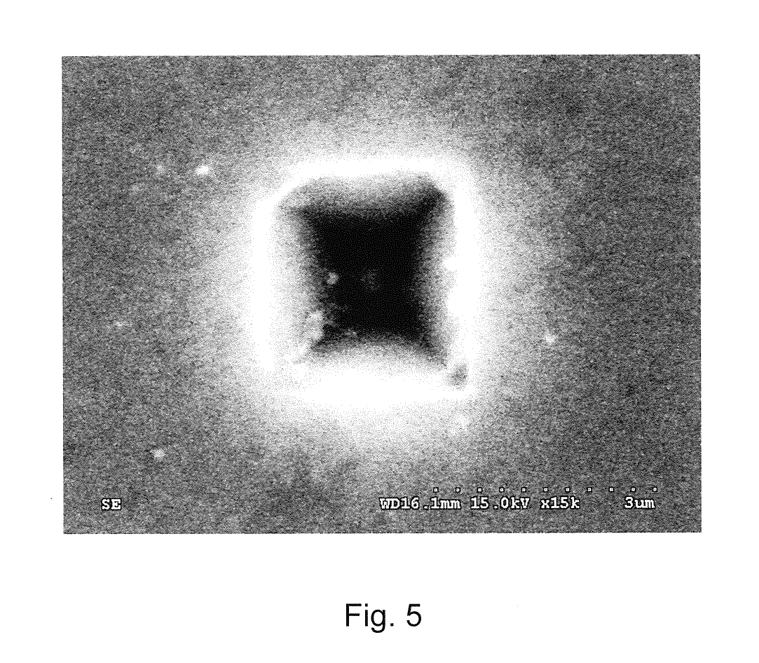

FIG. 5 shows an electron microscope photo after 250° C. thermal treatment and removing metal layers or the island structures of chrome, platinum, gold, and silver covered on the first silicon wafer 1 using aqua regia. It is observed that there are traces of pyramidal etch pits on the surface of the silicon wafer, which proves occurrence of reactions in the gold-silver-silicon ternary bonding system at the 250° C. low temperature thermal process. Thereby, the combination of gold and silver can be used for design the structure and the operating method and realizing the bonding purpose for gold-silicon bonds in the condition of 250° C. thermal treatment.

To sum up, the present invention discloses a method for ternary wafer bonding and the structure thereof. According to the present invention, silver island structures are distributed on the metal thin film deposited on the surface of a single silicon wafer for forming a gold-silver combination structure, which is then bonded with another silicon wafer without any metal layers thereon. Thus, the process of wafer bonding is simplified significantly. In addition, by incorporating the metal silver, the gold-silicon eutectic point is lowered. At a low-temperature thermal treatment of 250° C., wafer bonding can be achieved, which eliminates the problem in quality caused by stress in bonded wafers. Considering the cost, temperature, time, and quality in products of wafer bonding, the present undoubtedly provides a method for ternary wafer bonding and the structure thereof exhibiting practicability and economic values.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A method for ternary wafer bonding, comprising steps of:
vapor depositing a first bonding layer on a first silicon wafer;
disposing a second bonding layer on said first bonding layer, and said second bonding layer including a plurality of island structures distributed on said first bonding layer and exposing a portion of said first bonding layer;
disposing a second silicon wafer on said second bonding layer; and
performing thermal treatment for producing ternary bonding among said second silicon wafer, said first bonding layer, and said second bonding layer;
wherein the material of said first bonding layer is gold and the material of said second bonding layer is silver.

2. The method for ternary wafer bonding of claim 1, wherein the ratio of the diameter to the height of said plurality of island structures is between 900 and 1300.

3. The method for ternary wafer bonding of claim 2, wherein a spacing exists between any adjacent two of said plurality of island structures and the ratio of the diameter to the spacing of said plurality of island structures is between 4.75 and 4.50.

4. The method for ternary wafer bonding of claim 3, wherein the diameter of said plurality of island structures is between 900 and 950 micrometers.

5. The method for ternary wafer bonding of claim 1, and before said step of vapor depositing said first bonding layer on said first silicon wafer, further comprising steps of:
vapor depositing an adhesion layer on said first silicon wafer; and
vapor depositing a barrier layer on said adhesion layer.

6. The method for ternary wafer bonding of claim 5, wherein the material of said adhesion layer is chrome.

7. The method for ternary wafer bonding of claim 5, wherein the material of said barrier layer is platinum.

8. The method for ternary wafer bonding of claim 1, wherein the temperature for thermal treatment in said step of performing thermal treatment is 250° C.

9. The method for ternary wafer bonding of claim 1, wherein the time for thermal treatment in said step of performing thermal treatment is three hours.

10. The method for ternary wafer bonding of claim 1, and before said step of disposing said second bonding layer on said first bonding layer, further comprising a step of cleaning the surface of said second silicon wafer using aqua regia.

11. A structure of ternary wafer bonding, comprising:
a first silicon wafer;
a first bonding layer, disposed on said first silicon wafer;
a second bonding layer, disposed on said first bonding layer, and including a plurality of island structures distributed on said first bonding layer and exposing a portion of said first bonding layer; and
a second silicon wafer, bonded on said first bonding layer and said second bonding layer by thermal treatment;
where the material of said first bonding layer is gold and the material of said second bonding layer is silver.

12. The structure of ternary wafer bonding of claim 11, wherein the ratio of the diameter to the height of said plurality of island structures is between 900 and 1300.

13. The structure of ternary wafer bonding of claim 12, wherein a spacing exists between any adjacent two of said plurality of island structures and the ratio of the diameter to the spacing of said plurality of island structures is between 4.75 and 4.50.

14. The structure of ternary wafer bonding of claim 13, wherein the diameter of said plurality of island structures is between 900 and 950 micrometers.

15. The structure of ternary wafer bonding of claim 11, and further comprising an adhesion layer and a barrier layer bottom-up sequentially between said first silicon wafer and said first bonding layer.

16. The structure of ternary wafer bonding of claim 15, wherein the material of said adhesion layer is chrome and the material of said barrier layer is platinum.
